(19) United States
(12) Patent Application Publication
(10) Pub. No.: US 2021/0399047 A1
(43) Pub. Date: Dec. 23, 2021

(54) HETEROJUNCTION THIN FILM DIODE

(71) Applicant: International Business Machines Corporation, Armonk, NY (US)

(72) Inventors: Ning Li, White Plains, NY (US); Devendra K. Sadana, Pleasantville, NY (US); Wanki Kim, Chappaqua, NY (US)

(21) Appl. No.: 16/907,065

(22) Filed: Jun. 19, 2020

(51) Int. Cl. H01L 27/24; H01L 29/66; H01L 29/861; H01L 45/00; G11C 13/00

(52) U.S. Cl. CPC H01L 27/2409; H01L 29/6609; G11C 13/0004; H01L 45/12; H01L 29/861

(57) ABSTRACT

A diode is made of a p-type layer and an n-type layer connected in series between a bottom and top electrode. The p-type and n-type layers have a thickness below 20 nm. A p-type dopant concentration and an n-type dopant concentration are high enough to keep a total resistance across the diode at less than 250Ω when the diode is forward biased while still retaining the characteristics of a diode. In some embodiments, the ratio of an ON current to an OFF current is greater than 2.5×10⁴. Alternate embodiments of the diode, arrays of diodes and methods of making diodes are disclosed. Example arrays include memory arrays using diodes and phase change memories (PCMs) connected in series as array elements. The arrays can be stacked in layers and can be made/embodied in the back-end-of-the line (BEOL).

### BACKGROUND

The present invention relates to diodes, methods of making diodes, and uses of diodes in circuitry. More specifically, the invention relates to low leakage current thin film diodes, making thin film diodes, and using thin film diodes in circuits like semiconductor memories.

Diodes are electrical components that permit current flow when forward biased, e.g. a voltage is applied in a forward direction, but do not permit current flow when reversed biased, e.g. when the voltage is applied in a reverse direction. Thin film diodes are manufactured in semiconductor processes and are integrated ubiquitously in electronic circuitry.

Ideally, a diode will have a low resistance when forward biased and infinite resistance when reversed biased. In other words, the ratio of current through the diode while the diode is forward biased, e.g. in the “on” state, to the current through the diode while reversed biased, e.g. in the “off state”, should be very high. This ratio is called the “on/off ratio”.

However, physical diodes have leakage current—the current flow through the diode when diode is reversed biased. As circuitry becomes denser, e.g. there are more diodes per surface area on a substrate, the aggregate leakage current of large numbers of diodes in the circuitry can cause excess heating of the circuitry and higher power losses.

In addition, while diodes are easily integrated in semiconductor layers, e.g. on semiconductor substrates, manufacture of diodes on dielectric surfaces is more difficult.

There is a need for a diode structure with a high on/off ratio that can be made in both semiconductor circuitry and on dielectric surfaces that are encountered in back end of the line (BEOL). There is also a need to manufacture structures of diodes, e.g. used with phase change memories (PCMs), in the BEOL. Further, there is a need to stack diodes and/or array elements on multiple levels on one or more dielectric substrates.

### SUMMARY

According to some embodiments, a diode is made of a p-type layer and an n-type layer connected in series between a bottom and top electrode. The p-type layer has a p-type thickness below 20 nanometers (nm), a p-type dopant, and a p-type dopant concentration. The n-type layer has an interface with the p-type layer. An optional, very thin inter-facial layer (ITL) can be disposed between the p-type and n-type layer. The interface forms a p-n junction and the diode. The n-type layer has an n-type thickness below 20 nm, an n-type dopant, and an n-type dopant concentration. The p-type and n-type layer can be deposited/stacked in either order so the bottom electrode can be connected to either the p-type layer or the n-type layer. The top electrode is connected to the other of the p-type layer and the n-type layer.

The p-type dopant concentration and the n-type dopant concentration are high enough to keep a total resistance across the diode at less than 250Ω when the diode is forward biased while still retaining the characteristics of a diode. In some embodiments, the ratio of an ON current to an OFF current is greater than 2.5×10⁴.

Arrays of diodes and methods of making diodes are disclosed. Example arrays include memory arrays using diodes and phase change memories (PCMs) connected in series as array elements. The arrays can be stacked in layers and can be made/embodied in the back-end-of-the line (BEOL).

### BRIEF DESCRIPTION OF THE DRAWINGS

Various embodiments of the present invention will be described below in more detail, with reference to the accompanying drawings, now briefly described. The Figures show various apparatus, structures, and related method steps of the present invention.

FIG. 1 is a cross-section view of one embodiment of an interim layered structure, e.g. a nanosheet stack.

FIG. 2 is a cross-section view of an alternative embodiment of an interim layered structure.

FIG. 3 is a cross-section view of alternative embodiments of a heterojunction thin film diode.

FIG. 4 is an isometric view of one embodiment of a phase change memory structure using heterojunction thin film diodes.

FIG. 5 is a circuit schematic of one embodiment of a phase change memory structure using heterojunction thin film diodes.

FIG. 6 is a flow chart of one method of making an embodiment of a heterojunction thin film diode.

### DETAILED DESCRIPTION

It is to be understood that embodiments of the present invention are not limited to the illustrative methods, apparatus, structures, systems and devices disclosed herein but instead are more broadly applicable to other alternative and broader methods, apparatus, structures, systems and devices that become evident to those skilled in the art given this disclosure.

In addition, it is to be understood that the various layers, structures, and/or regions shown in the accompanying drawings are not drawn to scale, and that one or more layers, structures, and/or regions of a type commonly used may not be explicitly shown in a given drawing. This does not imply that the layers, structures, and/or regions not explicitly shown are omitted from the actual devices.

In addition, certain elements may be left out of a view for the sake of clarity and/or simplicity when explanations are not necessarily focused on such omitted elements. Moreover, the same or similar reference numbers used throughout the drawings are used to denote the same or similar features, elements, or structures, and thus, a detailed explanation of the same or similar features, elements, or structures may not be repeated for each of the drawings.

The semiconductor devices, structures, and methods disclosed in accordance with embodiments of the present invention can be employed in applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, expert and artificial intelligence systems, functional circuitry, neural networks, etc. Systems and hardware incorporating the semiconductor devices and structures are contemplated embodiments of the invention.

As used herein, “height” refers to a vertical size of an element (e.g., a layer, trench, hole, opening, etc.) in the cross-sectional or elevation views measured from a bottom surface to a top surface of the element, and/or measured with respect to a surface on which the element is located.

Conversely, a “depth” refers to a vertical size of an element (e.g., a layer, trench, hole, opening, etc.) in the cross-sectional or elevation views measured from a top surface to a bottom surface of the element. Terms such as “thick”, “thickness”, “thin” or derivatives thereof may be used in place of “height” where indicated.

As used herein, “lateral,” “lateral side,” “side,” and “lateral surface” refer to a side surface of an element (e.g., a layer, opening, etc.), such as a left or right-side surface in the drawings.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

As used herein, terms such as “upper”, “lower”, “right”, “left”, “vertical”, “horizontal”, “top”, “bottom”, and derivatives thereof shall relate to the disclosed structures and methods, as oriented in the drawing figures. For example, as used herein, “vertical” refers to a direction perpendicular to the top surface of the substrate in the elevation views, and “horizontal” refers to a direction parallel to the top surface of the substrate in the elevation views.

As used herein, unless otherwise specified, terms such as “on”, “overlying”, “atop”, “on top”, “positioned on” or “positioned atop” mean that a first element is present on a second element, wherein intervening elements may be present between the first element and the second element. As used herein, unless otherwise specified, the term “directly” used in connection with the terms “on”, “overlying”, “atop”, “on top”, “positioned on” or “positioned atop,” “disposed on,” or the terms “in contact” or “direct contact” means that a first element and a second element are connected without any intervening elements, such as, for example, intermediary conducting, insulating or semiconductor layers, present between the first element and the second element.

It is understood that these terms might be affected by the orientation of the device described. For example, while the meaning of these descriptions might change if the device was rotated upside down, the descriptions remain valid because they describe relative relationships between features of the invention.

Refer now to the Figures.

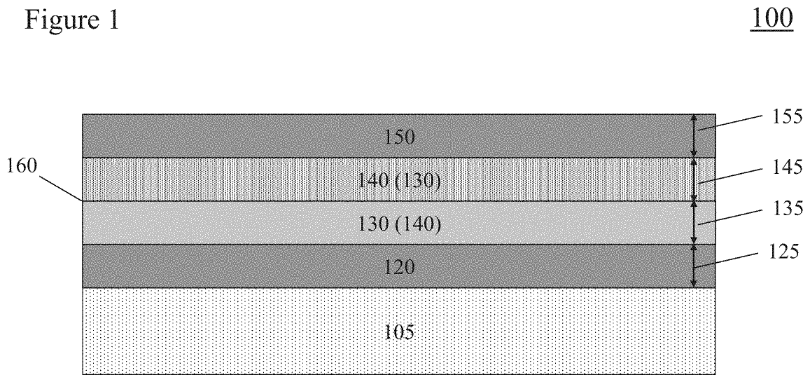

FIG. 1 is a cross-section view of one embodiment of an interim layered structure 100, e.g. a nanosheet stack 100.

The beginning layered structure 100 is a layer of nanosheets disposed on a substrate 105. Nanosheet 120 is a layer of conductive material that is used as a first electrode or contact 120 of a diode 160. Layers 130 and 140 are each made of p-type or n-type materials, disposed adjacent to one another (in either order) to form a p-n junction 160 that makes the diode 160. Nanosheet layer 150 is another layer of conductive material that is used as a second electrode 150 or contact of the diode 160.

In one embodiment, the substrate 105 is made of a semiconductor material(s) including: a single element (e.g., silicon or germanium); primarily a single element (e.g., a doped material), for example doped silicon; a compound semiconductor, for example, gallium arsenide (GaAs); or a semiconductor alloy, for example silicon-germanium (SiGe). Non-limiting examples of the substrate 105 materials include one or more semiconductor materials like silicon (Si), SiGe, Si:C (carbon doped silicon), germanium (Ge), carbon doped silicon germanium (SiGe:C), Si alloys, Ge alloys, III-V materials (e.g., GaAs, Indium gallium arsenide (InGaAs), indium arsenide (InAs), indium phosphide (InP), aluminum arsenide (AlAs), etc.), II-V materials (e.g., cadmium selenide (CdSe), cadmium sulfide (CdS), or any combination thereof), or other like semiconductors. In addition, multiple layers of the semiconductor materials can make up the substrate 105. In some embodiments, the substrate 105 includes both semiconductor materials and dielectric materials. In some silicon on insulator (SOI) implementations, a buried oxide layer, BOX, (e.g., SiO2) is buried in the substrate 105.

These embodiments of the diode 160 can be used in layers of semiconductor devices that include other active or passive elements like field effect transistors (FETs), capacitors, inductors, etc.

In other embodiments, the substrate 105 is made of a dielectric or insulating material. Dielectric materials include, but are not limited to: dielectric oxides (e.g. silicon oxide, SiOx); dielectric nitrides (e.g., silicon nitride, SiN; siliconborocarbonitride, SiBCN; siliconcarbonitride, SiCN; and siliconboronitride SiBN); dielectric oxynitrides (e.g., silicon oxycarbonitride, SiOCN, and silicon oxynitride, SiON); silicon carbide (SiC); silicon oxycarbide (SiCO); or any combination thereof or the like.

Dielectric materials are often encountered in the back-end-of-the-line (BEOL) where the dielectric materials act as electrical insulators. Since the BEOL provides a plurality of interconnection layers, the layers of the BEOL often have conductive interconnections running through the dielectric/insulating layers.

In embodiments of the invention, the layers (120, 130, 140, and 150) of the diode 160 can be formed by deposition. Therefore, the heterojunction thin film diode 160 can be formed using one or more of BEOL dielectric layers as the substrate 105. In addition, multiple diodes 160 can be made in a stacked formation(s) of multiple layers of diodes 160 (e.g., a three-dimensional, 3D, stacking) on one or more dielectric layers/substrates 105 in the BEOL. Accordingly, the diode 160 structure and methods of making the diode(s) 160 enable diode circuitry, e.g. used with phase change memories (PCMs), to be formed in the BEOL and that are compatible with BEOL manufacturing processes.

Layers 130 and 140 are made of either a p-type or an n-type material. Layers 130 and 140 have opposite types. For example, layer 130 is a p-type material and layer 140 is an n-type material. Alternatively, layer 140 is the p-type material and layer 130 is the n-type material. Since layers 130 and 140 are of opposite types, a p-n junction 160 forming the diode 160 is created at the interface 160 of the layers 130 and 140. While the order of the layers 130 and 140 does not matter in creating the diode 160 (only that the layers, 130 and 140, are in substantial contact and opposite in type), the direction of current flow or blockage will change, e.g. from the first electrode 120 to the second electrode 150 or visa versa, depending on the ordering of the type of materials in layers 130 and 140 in the layered structure 100. The diode 160 has a heterojunction because layers 130 and 140 forming the p-n junction are made from two different materials.

The first electrode or contact 120 and the second electrode or contact of the diode 160 are each made of a layer 120 (150) of conductive material, e.g. metal. Non-limiting examples of metals include: copper, Cu; tungsten, W; aluminum, Al; nickel, Ni; thallium nitride, Tl3N; and titanium nitride, TiN. In some embodiments, the first 120 and second 150 electrodes are made of Al. In some embodiments, the first electrode 120 may be electrically insulated from the substrate 105.

The first electrode 120 and/or second electrode 150 can be deposited by atomic layer deposition (ALD), chemical vapor deposition (CVD), Plasma Enhanced Chemical Vapor Deposition (PECVD), Radio Frequency Chemical Vapor Deposition (RFCVD,) Physical Vapor Deposition (PVD), Pulsed Laser Deposition (PLD), Liquid Source Misted Chemical Deposition (LSMCD), and/or sputtering.

In some embodiments, the thickness 125 of the first electrode 120 and the thickness 155 of the second electrode 150 is between 50 nanometers (nm) and 100 nm.

In some embodiments, the p-type layer 130 (140) and the n-type layer 140 (130) are made of semiconductor materials. Non-limiting examples of these semiconductor materials include silicon (Si), germanium (Ge), and silicon germanium (SiGe).

The p-type layer 130 (140) and the n-type layer 140 (130) can be deposited by ALD, CVD, PECVD, RFCVD, PVD, PLD, and Liquid Source Misted Chemical Deposition (LSMCD). The thicknesses (135, 145) of these layers (130, 140) is between 5 nm and 30 nm, respectively. In some embodiments, the thicknesses (135, 145) are less than 20 nm.

The p-type layer 130 (140) and the n-type layer 140 (130) are doped. As an example, the p-type layers 130 (140) is doped with dopants selected from a non-limited group of boron (B), gallium (Ga), indium (In), and thallium (Ti). The n-type layer 140 (130) is doped with dopants selected from a non-limited group of phosphorus (P), arsenic (As), and antimony (Sb).

In alternative embodiments, the n-type layer 140 (130) is a doped metallic layer 140 (130). As a non-limiting example, the n-type layer 140 (130) can be made of a metal like Al doped with zinc oxide (ZnO).

There is a trade-off consideration with the doping levels of the p-type 130 (140) and n-type 140 (130) layers. To achieve a low resistance, e.g. high “on current” when the diode 160 is forward biased, the p-type 130 (140) and n-type 140 (130) layers have to be highly conductive. However, if one or both layers is too conductive, e.g. too highly doped, the interface 160 will behave more like an electrical contact than a diode and/or the leakage current when reversed biased will be too high.

In some embodiments, the doping level/concentration for the p-type layer 130 (140) is between 1×10¹⁸ cm⁻³ and 1×10²¹ cm⁻³ and the doping level/concentration for the n-type layer 140 (130) is between 1×10¹⁸ cm⁻³ and 4%.

In some embodiments, the p-type layer 130 (140) is Ge or SiGe doped with P or As at a concentration between 1×10¹⁹ cm⁻³ and 1×10²¹ cm⁻³ and the n-type layer 140 (130) is Ge or SiGe doped with P or As at a concentration between 1×10¹⁹ cm⁻³ and 1×10²¹ cm⁻³. In alternative embodiments, the n-type layer 140 (130) is a thin metallic film between 5 and 20 nm thick 145 made of Al doped with ZnO at a concentration between 1% and 4%.

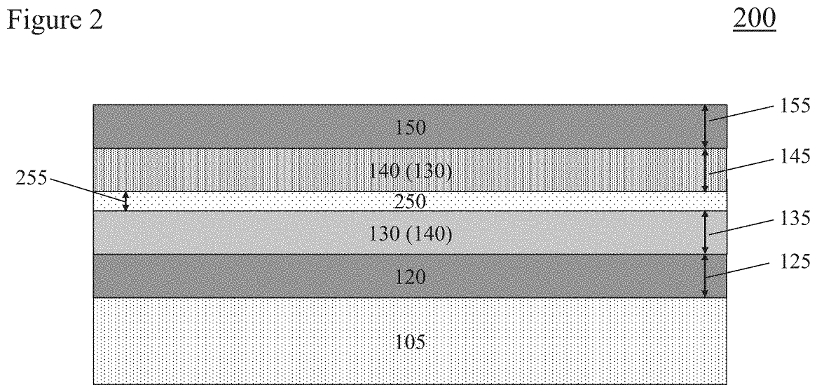

FIG. 2 is a cross-section view of an alternative embodiment of an interim layered structure 100. In this embodiment, a very thin inter-facial layer (ITL) 250 is disposed between the p-type 130 (140) and n-type 140 (130) layers. In some embodiments, the ITL 250 is has a thickness 255 between 1 nm and 5 nm. In some embodiments, the ITL 250 has a thickness 255 of about 3 nm.

While the p-type 130 (140) and n-type 140 (130) layers are substantially in contact, the ITL 250 creates a tunneling barrier between the p-type 130 (140) and n-type 140 (130) layers. Because of the ITL 250 thinness 255, the barrier has little effect when the diode is forward biased. However, when the diode is reversed biased, the barrier increases greatly. Therefore, in the reversed biased configuration the ITL 250 significantly reduces the leakage current and improves the on/off current ratio of the diode.

In some embodiments, the ITL 250 is made of a dielectric material that is deposited by one or more of the deposition techniques described above. In some embodiments, the ITL 250 is made of silicon dioxide (SiO₂) or aluminum oxide (Al₂O₃).

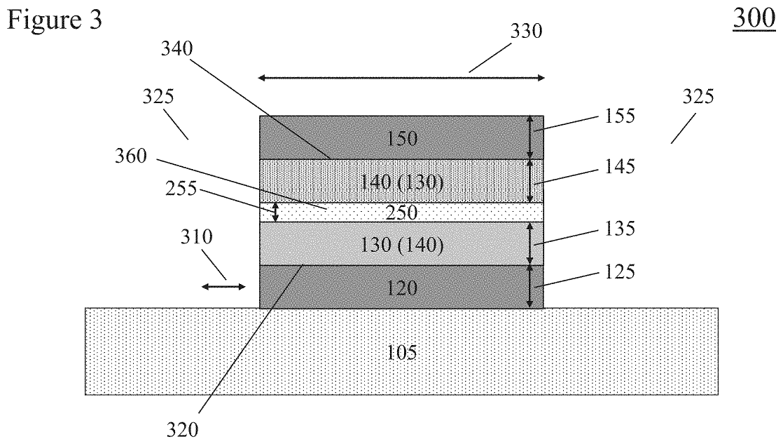

FIG. 3 is a cross-section view of alternative embodiments of a heterojunction thin film diode 300. The embodiment is shown with an ITL 250 but an embodiment without an ITL 250 is also contemplated without loss of generality. The diode 160 with the ITL 250 is shown as diode 360. As discussed above, the substrate 105 can be made of semiconductor material or dielectric material without loss of generality. In addition, as discussed above, the p-type 130 (140) and n-type 140 (130) layers can be in reversed positions.

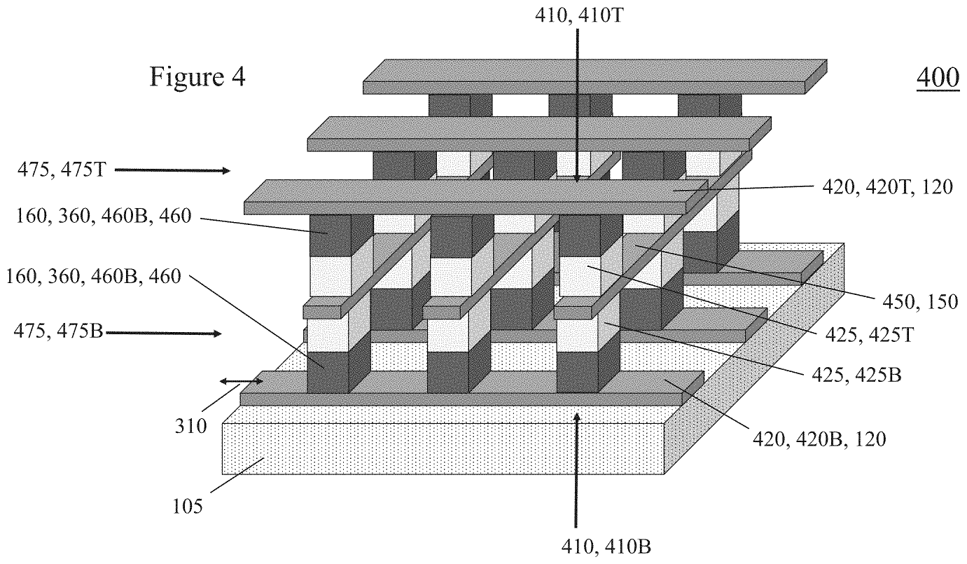

Material 325 is removed on either side (and front and back, not shown) of the structure 300 by known masking and etching methods. As shown in FIG. 4, these masking/etching steps can create a pattern of diodes 160/360 in one or more arrays with spacing between the diodes 160/360. The etching can occur in multiple steps using different chemistries as different layers (120, 130, 250, 140, and 150) are etched away.

In alternative embodiments, techniques can be employed to make the bottom 120 and/or top 150 electrode layers longer/wider 310 than the length/width of the p-type 130 (140) and n-type 140 (130) layers and ITL 250. Using known masking and/or deposition techniques, the bottom 120 and/or top 150 electrode layers can be extended 310 to create 3D structures like those described in the memory structures below.

A non-limiting example is now presented. In this example embodiment, the p-type 130 layer is made of Ge at a doping concentration between 1×10¹⁸ cm⁻³ and 1×10²¹ cm⁻³. The n-type layer 140 is made of Al doped with ZnO at a doping concentration between 0.1% and 8%. There is no ILT layer 250. The top 150 and bottom 120 electrodes are made of a metal, like Al.

The resistance of the layers and the contact interfaces between the layers and metal electrodes (120, 150) are each determined to calculate the total series resistance of the device 300.

The contact resistance 320 of the interface 320 between the metal (Al) bottom electrode 120 and the Ge p-type layer 130 (e.g. measured by the I-V curve slope at zero volts) can be as low as 1×10⁻¹⁰ Ω-cm² with the levels of doping in the example. Accordingly, for a diode 160 with a width 330 of 100 nm and a depth (not shown) of 100 nm (i.e. a diode 160 of 100 nm×100 nm size/surface area) the contact resistance 320 will be about 1Ω. For instance:

R₃₂₀=1×10⁻¹⁰ Ω-cm²/(10⁻⁵ cm×10⁻⁵ cm)=1Ω, i.

where a 100 nm distance (here both width 330 and depth, not shown) is 10⁻⁵ cm.

Similarly, the resistance of p-type (Ge) layer 130 is:

R₁₃₀=0.005 Ω-cm*20 nm/(10⁻⁵ cm×10⁻⁵ cm)=100 Ω, i.

where 20 nm is the thickness 135 of the p-type layer and 0.005 Ω-cm is the resistivity of Ge.

The resistance of the n-type (Al:ZnO) layer 140 is:

R₁₄₀=0.0014 Ω-cm*20 nm/(10⁻⁵ cm×10⁻⁵ cm)=28Ω, i.

where 20 nm is the thickness 145 of the n-type layer 140 and 0.005 Ω-cm is the resistivity of Al doped with ZnO at the given concentration.

Finally, the contact resistance at the interface 340 between the n-type (Al:ZnO) layer 140 and the metal (Al) top electrode 150 can be as low as 1×10⁻⁸ Ω-cm² with the levels of doping in the example, yielding a contact resistance at this interface 340 of

R₃₄₀=1×10⁻⁸ Ω-cm²/(10⁻⁵ cm×10⁻⁵ cm)=100Ω, i.

for the 10⁻⁵ cm×10⁻⁵ cm size diode 160/360.

Therefore, the total series resistance R_{T} of the device 160 is:

R_{T}=R₃₂₀+R₁₃₀+R₁₄₀+R₃₄₀,=approximately 200Ω, i.

where the major contributions to the total resistance is the resistance of the p-type layer 130, R₁₃₀, and the n-type layer 140, R₁₄₀.

Accordingly, the doping levels/concentration of the p-type layer 130 and the n-type layer 140 are made high to keep the resistance of both of the p-type 130 and n-type 140 layers low, but these doping concentrations are low enough to still maintain the p-n junction interface 160/360 as a diode.

These values are specific for p-Ge and Al:ZnO example junction. The contact resistance 320 to the p-Ge layer 130 is very low but the contact resistance to the Al:ZnO 140 is higher.

In this example, a forward voltage of 1 volt (V) across a total resistance, R_{T}, of approximately 200Ω, will result in a forward current through the diode 160, I, equal to 1 V/200Ω=0.5 mA=5 MA/cm².

Based on the measured I-V of this example Al:ZnO/Ge diode 160 and a theoretical total forward resistance of 200Ω forward currents at different voltages are provided in the table below:

| Voltage | 0.5 V | 0.75 V | 1 V | 1.5 V | 2 V | 3 V |
|---|---|---|---|---|---|---|
| Current | 20 A/cm² | 200 A/cm² | 2 kA/cm² | 10 kA/cm² | 50 MA/cm² | 100 MA/cm² |

Where “MA” is 10⁶ Amperes and “kA” is 10³ Amperes.

The current, I, was calculated as I=50 MA/cm² at 2V. The current at other voltages are calculated from the diode I-V curve, assuming I=50 MA/cm2 at 2V.

Analysis was performed to determine the “on/off ratio”. A comparison was made between the forward current, or “ON current”, at a forward bias voltage Vₒₙ, to an “OFF Current” when reverse biasing the diode 160 at a reverse bias voltage, V_{off}, is applied, where

V_{off}=Vₒₙ/2. i.

As a non-limiting example, at a Vₒₙ=2V the forward current through the diode 160 Iₒₙ=50 MA/cm² while at V_{off}=1V, the leakage current, I_{off}=2 k A/cm².

In this example, the On/Off current ratio is 2.5×10⁴.

One example design criterion for an N×N array of diodes is that:

I_{off}<Iₒₙ/(10×N) at V_{off}=Vₒₙ/2, or 1.

Iₒₙ/I_{off}>(10×N), 2.

where N is the dimension of one side of a square array of diodes.

Therefore, diodes 160/360 having an On/Off current ratio, Iₒₙ/I_{off}, of 2.5×10⁴ or better can be used in diode arrays where N×N is up to 1000×1000 and still satisfy this design requirement.

To create larger N×N arrays that meet this design requirement, the p-type layer 130 can be made from Si or SiGe which will reduce the On/Off current ratio when V_{off}=Vₒₙ/2.

FIG. 4 is an isometric view of an array 400 of heterojunction thin film diodes (160, 360) used with an array of phase change memories (PCM), each PCM typically 425.

PCMs 425 are known circuit elements that manifest two or more states, e.g. resistance values, that can be set and reset and read to store/retrieve a memory state.

The array 400 is disposed on a substrate 105. For arrays built in the BEOL, alternative embodiments of the substrate 105 can be made of a dielectric, rather than a semiconductor material, as described above.

In one form, the array is made of one or more array elements, typical 410. An array element can be a diode (160, 360) alone. In the PCM array embodiment 400 shown, an array element is a diode (160, 360) in series with a PCM, 425 between a bottom array 420B and a top array 450 electrode.

One or more of the array elements 425 can be stack upon one 475 another 475. For example, in the PCM array embodiment 400, there is a first array layer (475B, typically 475), each array layer 475 has one or more bottom array elements (410B, typically 410). The bottom array elements (410B, 410) have a first bottom array electrode (420B, typically 420), a bottom diode (160, 360, 460B, typically 460), a bottom PCM (425B, typically 425), and a first top array electrode (450).

In this embodiment, a second or top array layer (475T, 475) is stacked upon the first or bottom array layer (475B, 475). The second or top array layer 475T has one or more top array elements (410T, typically 410). Each of the top array elements 410T has a second bottom array electrode (420T, typically 420), a top diode (160, 360, 460T, typically 460), a top PCM (425T, typically 425), and a second top array electrode 450.

Note that in this embodiment, the first top array electrode 450 and the second top array electrode 450 are the same element, namely a common top array electrode 450. In other words, one or more of the bottom array elements 410B and one or more of the top array elements 410T are connected in common by the top electrode 450. In a sense, in this embodiment 400, the top array layer 475T is a “flipped” version of the bottom array layer 475B.

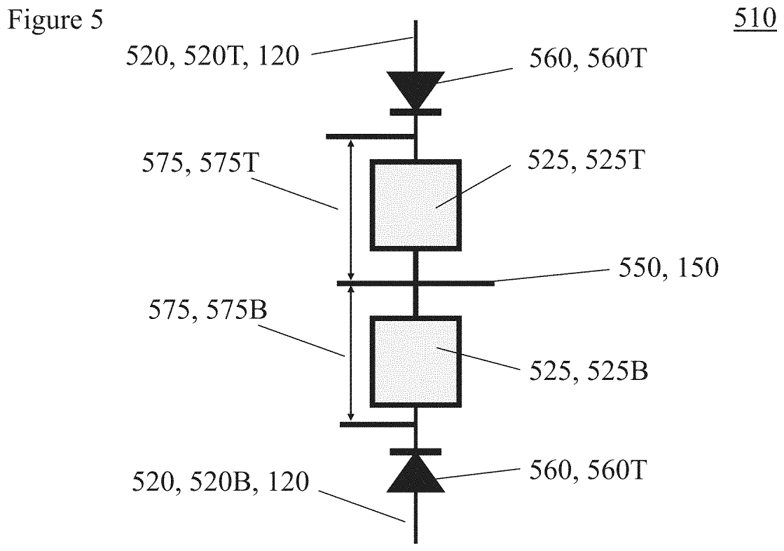

In addition, note that in this embodiment 400 (and that shown in FIG. 5), the diodes (160, 360, 460) in one or more of the bottom 410B and top 410T array elements 410T have the same polarity or direction. In other words, each of the one or more bottom 410B and top 410T array elements 410T connected in common has a diode 460 with the same layer position for the p-type 130 (140) and n-type 140 (130) layers.

In alternative embodiments, one or more bottom 410B array elements has the bottom diode 460B with the p-type 140 (130) and n-type 130 (140) layers reverse from the top diode 460T in an associated or connected top 410T array element 410T. In these cases, the bottom 410B and top 410T array elements would be connected in series. In other words, in this alternative embodiment, top electrode 450 of the bottom array element 410B is connected to the second bottom electrode (120, 420T).

Accordingly, the connections/configuration of the array 400 can be adjusted by both how the array elements 410 are interconnected and/or how they are constructed.

In the embodiment shown 400, the first 120 and second 150 electrodes are shown elongated 310. The elongated 310 first 120 and second 150 electrode can become or be connected to the respective array electrodes (420, 450) that connect two or more array elements 410. Alternate embodiments are envisioned where one or more of the first array 420 and second array 450 electrodes connect to just one, two, or many array elements 410.

FIG. 5 is a circuit schematic 500 of a phase change memory structure using heterojunction thin film diodes (160, 360, in this schematic typically 560).

In this embodiment, the diodes (160, 360, 560) are made the same way, e.g. the diodes (160, 360, 560) and have the same polarity because the p-type layer 130 (140) and the n-type layer 140 (130) are layered in the same sequence for each of the diodes (160, 360, 560). The top diode (560T, typically 560) and bottom diode (560B, typically 560) are connected though a respective top PCM (525T, typically 525) and bottom PCM (525B, typically 525) so that the top electrodes (150, 550) of the diodes are connected in common 550 through their respective PCMs 525.

When the common connection 550 is at a lower voltage, e.g. ground voltage, and a higher voltage is applied to the bottom electrode 120 of top diode 560T (i.e. bottom electrode 520T, typically 520, or 120) and/or the bottom electrode 120 of bottom diode 560B (i.e. bottom electrode 520B, typically 520, or 120), a current flows through the respective diode 560 and its associated PCB 525. A top voltage 575T (typically 575) can be read across the top PCM 525T and/or a bottom voltage 575B (typically 575) can be read across the bottom PCM 525B. A lower voltage 575 reading indicates the respective PCM 525 is in a lower resistive or first memory state. A higher voltage 575 reading indicates the respective PCM 525 is in a higher resistive or second memory state. If the polarity of the applied voltage reverse biases either the top 525T and/or bottom 525B diode 525, no or very little current will flow through the “Off” diode 560 and its associated PCM 525 because the diodes (160, 360, 560) have such a low leakage current and such a high On/Off current ratio. In such “Off” condition no or little voltage 575 will be read.

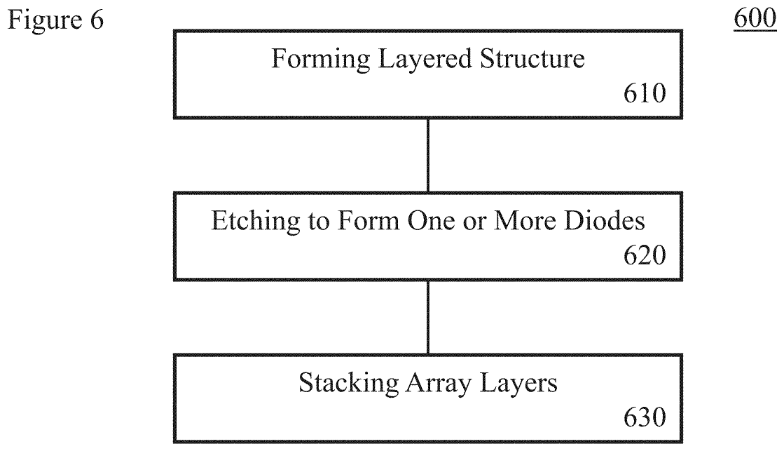

FIG. 6 is a flow chart of the method of making 600 a heterojunction thin film diode (160, 360).

The method 600 begins with step 610 which forms a layered structure 100, either on a semiconductor or dielectric substrate 105. The layered structure 100 formed on a dielectric substrate 105 can be formed at the BEOL. The layered structure includes the substrate 105, the first/bottom electrode 120, the p-type layer 130 (140), the n-type layer 140 (130), and the second/top electrode 150. The p-type 140 (130) and n-type 130 (140) layers can be formed in reverse order. Optionally, an ITL layer 250 is formed between the p-type layer 130 (140) and the n-type layer 140 (130). Further details including doping levels are included in the description of FIGS. 1 and 2.

In step 620 of the process, an etching is formed to define one or more diode (160, 360) structures 300. The first/bottom 120 and/or second/top 150 electrodes can be formed under a single device (160, 360) and/or can be elongated 310 by known lithographic techniques to connect to two or more devices (160, 360), e.g. array elements 140.

In step 630 array layers 475 can be stacked one upon the other 475 to form multiple different array configurations. PCMs 425 can be integrated into the arrays 400 to create memory structures, e.g. in the BEOL, either at one level 475 or at two or more multiple levels (475B, 475T, 475).

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. For example, the semiconductor devices, structures, and methods disclosed in accordance with embodiments of the present invention can be employed in applications, hardware, and/or electronic systems. Systems and hardware incorporating the semiconductor devices are contemplated embodiments of the invention.

The terminology used herein was chosen to explain the principles of the embodiments and the practical application or technical improvement over technologies found in the marketplace or to otherwise enable others of ordinary skill in the art to understand the embodiments disclosed herein. Devices, components, elements, features, apparatus, systems, structures, techniques, and methods described with different terminology that perform substantially the same function, work in the substantial the same way, have substantially the same use, and/or perform the similar steps are contemplated as embodiments of this invention.

We claim:

1. A diode comprising:
a p-type layer, the p-type layer having a p-type thickness below 20 nanometers (nm), a p-type dopant, and a p-type dopant concentration;
an n-type layer having an interface with the p-type layer, the interface forming a p-n junction and the diode, the n-type layer having an n-type thickness below 20 nm, an n-type dopant, and an n-type dopant concentration;
a bottom electrode connected to one of the p-type layer and the n-type layer; and
a top electrode connected to one of the p-type layer and the n-type layer, but not a layer where the bottom electrode is connected.

2. A diode, as in claim 1, where the p-type dopant concentration and the n-type dopant concentration are high enough to keep a total resistance across the diode at less than 250Ω when the diode is forward biased.

3. A diode, as in claim 1, where a ratio of an ON current to an OFF current is greater than 2.5×10⁴, the ON current being a current flowing through the diode when the diode is in forward bias and the OFF current being the current flowing through the diode when the diode is in reverse bias.

4. A diode, as in claim 3, where reverse bias is where the a reverse voltage is applied in a reverse direction to turn the diode off, and the reverse voltage is ½ the magnitude of a forward voltage or less, the forward voltage being in a forward direction opposite the reverse direction, the forward voltage able to turn on the diode.

5. A diode, as in claim 1, where the p-type layer and n-type layer is made of one of the following: silicon (Si), germanium (Ge), and silicon-germanium (SiGe).

6. A diode, as in claim 1, where the p-type dopant is one or more of the following: boron (B), gallium (Ga), indium (In), and thallium (Tl).

7. A diode, as in claim 1, where the p-type dopant concentration is between 1×10¹⁸ cm⁻³ and 1×10²¹ cm⁻³.

8. A diode, as in claim 1, where the n-type dopant is one or more of the following: phosphorus (P), arsenic (As) and antimony (Sb).

9. A diode, as in claim 1, where the n-type dopant concentration is between 1×110 cm⁻³ and 1×10²¹ cm⁻³.

10. A diode, as in claim 1, where the n-type layer is made of a doped metal, the doped metal having a metal dopant concentration between 1% and 4%.

11. A diode, as in claim 1, where the n-type layer is made of aluminum (Al) doped with zinc oxide (ZnO).

12. A diode, as in claim 1, where the first electrode and the second electrode are made of one or more of the following metals: copper (Cu), tungsten (W), aluminum (Al), nickel (Ni), thallium nitride (Tl3N), and titanium nitride (TiN.

13. A diode, as in claim 1, further comprising a substrate and the substrate is made from one of a semiconductor material and a dielectric material.

14. A diode, as in claim 1, further comprising a substrate made from a dielectric material, the diode disposed on the dielectric material, the dielectric material being a back-end-of-the-line (BEOL) layer.

15. A diode, as in claim 1, electrically connected to a phase change memory (PCM) in series forming an array element.

16. A diode, as in claim 1, further comprising an inter-facial layer (ITL) between and in electrical contact with the p-type layer and the n-type layer, the ITL having a thickness between 1 nm and 5 nm, and the ITL made of a dielectric material.

17. A diode, as in claim 16, where the dielectric material is one of silicon dioxide (SiO₂) and aluminum oxide (Al₂O₃).

18. A memory array comprising:
one or more of diodes, each diode comprising:
a p-type layer, the p-type layer having a p-type thickness below 20 nanometers, a p-type dopant, and a p-type dopant concentration;
an n-type layer having an interface with the p-type layer, the interface forming a p-n junction and the diode, n-type layer having an n-type thickness below 20 nanometers, an n-type dopant, and an n-type dopant concentration;
a bottom electrode connected to one of the p-type layer and the n-type layer; and
a top electrode connected to one of the p-type layer and the n-type layer, but not a layer where the bottom electrode is connected;
one or more phase change memories (PCMs), each of the PCMs connected to one of the diodes in series, the PCM connected being an associated PCM, associated with the diode connected in series;
a bottom array electrode connected to one of the bottom electrode and the top electrode; and
a top array electrode connected to the associated PCM,
wherein the diode and the associated PCM are connected in series with and between the bottom array electrode and the top array electrode forming an array element in an array layer, being a first array layer.

19. A memory array, as in claim 18, where one or more second array layers are stacked upon the first array layer.

20. A method of making a diode comprising the steps of:
forming a layered structure by performing the steps of:
forming a substrate;
depositing a bottom electrode on the substrate;
depositing a p-type layer;
depositing an n-type layer, the n-type layer and p-type layer having an interface that forms a p-n junction and the diode, the p-type layer and n-type layer each having a thickness less than 20 nanometers; and
depositing a top electrode, the p-type layer and n-type layer being between the bottom electrode and top electrode and the bottom electrode, p-type layer, n-type layer, and top electrode electrically connected in series.
